(19) United States
(12) Patent Application Publication
(10) Pub. No.: US 2023/0068854 A1
(43) Pub. Date: Mar. 2, 2023

(54) METHOD OF MAKING A PLURALITY OF 3D SEMICONDUCTOR DEVICES WITH ENHANCED MOBILITY AND CONDUCTIVITY

(71) Applicant: Tokyo Electron Limited, Tokyo (JP)

(72) Inventors: H. Jim Fulford, Albany, NY (US); Mark I. Gardner, Albany, NY (US); Partha Mukhopadhyay, Albany, NY (US)

(73) Assignee: Tokyo Electron Limited, Tokyo (JP)

(21) Appl. No.: 17/893,736

(22) Filed: Aug. 23, 2022

Related U.S. Application Data
(60) Provisional application No. 63/239,880, filed on Sep. 1, 2021.

(51) Int. Cl. H01L 27/092; H01L 29/45; H01L 29/78; H01L 21/8238; H01L 21/822

(52) U.S. Cl. CPC H01L 27/0922; H01L 29/45; H01L 29/7827; H01L 21/823814; H01L 21/823871; H01L 21/823885; H01L 21/8221

(57) ABSTRACT

The solution provides a device formed in a layer stack that includes a source contact layer and a gate contact layer with a first insulation between the gate contact layer and the source contact layer and a drain contact layer with a second insulation between the gate contact layer and the drain contact layer. The layer stack can include a device region orthogonal to a plane defined by a surface of at least one of the layers of the stack. The device region includes a source and a drain separated by a channel at least partially surrounded by a gate dielectric interposed between the gate contact layer and the channel and a first region that can include a silicide or a germanicide at a first end proximal to the source and a second region that can include the silicide or the germanicide at a second end proximal to the drain.

### CROSS-REFERENCE TO RELATED APPLICATIONS

This application claims priority to U.S. Provisional Application Ser. No. 63/239,880, filed Sep. 1, 2021, which is incorporated by reference in its entirety.

### TECHNICAL FIELD

This disclosure related to microelectronic devices including semiconductor device, transistors, and integrated circuits, including methods of microfabrication.

### BACKGROUND

Fabrication of semiconductor devices relies on execution of various fabrication processes such as film-forming depositions, doping treatments, etch mask creation, patterning and material etching and removal. These processes are performed repeatedly in order to form desired semiconductor features on a substrate. While for many years, scaling efforts have increased the number of transistors per unit area in 2D circuits, in the more recent years, recently scaling challenges have emerged as semiconductor device features approached single digit nanometer fabrication nodes. Semiconductor device fabricators have expressed a desire to find new ways to overcome the scaling challenges.

### SUMMARY

When scaling semiconductor devices to feature sizes that are only several atoms thick, fabricators of integrated circuits (“IC”) have been increasingly encountering technical issues, such as leakage currents and short-channel effects. It has been observed that the smaller the space between active features of a semiconductor device the more pronounced these issues can be. The present disclosure provides solutions that overcome these issues by providing three-dimensional (3D) semiconductor circuits in which transistors can be stacked on top of each other, allowing for improved scaling (i.e., more circuits per unit area) while also preventing or limiting leakage currents, short channel effects. The present solution can also provide improved electrical properties of semiconductor structures fabricated in the 3D vertical orientation, utilizing chemical compounds formed between metals and semiconductors via annealing, such as silicide and germanicide regions, which can improve electrical response of their corresponding silicon-based and/or germanium-based transistor devices.

In one aspect, the present solution relates to a transistor structure. The transistor structure can include a stack of layers. The stack of layers can include a first device and a second device. The first device can include a first insulation layer between a source contact layer and a gate contact layer and a second insulation layer between a drain contact layer and the gate contact layer. The first device can include a device region orthogonal to a plane defined by a surface of at least one of the layers in the stack of layers. The device region can comprise a first semiconductor material, a source and drain separated by a channel region. The second device can be vertically aligned with the first device. The second device can include a third insulation layer between a second source contact layer and a second gate contact layer and a fourth insulation layer between a second drain contact layer and the second gate contact layer. The second device can include a second device region orthogonal to the plane and comprising a second semiconductor material, a second source and a second drain separated by a second channel region.

The transistor structure can include the gate contact layer at least partially surrounding the channel region with a gate dielectric interposed between the gate contact layer and the channel region. The first device can include silicide regions at ends of the device region proximal to the source and the drain. The second device can include germanicide regions at ends of the second device region proximal to the second source and the second drain. The transistor structure can include the gate contact layer forming a ring around the channel region with a gate dielectric interposed between the gate contact layer and the channel region. The transistor structure can include the device region of the first device comprising silicon and the second device region of the second device comprising germanium.

The transistor structure can include a first silicide region at a first end of the device region in electrical contact with the source and a second silicide region at a second end of the device region in electrical contact with the drain. The transistor structure can include a hollow core extending orthogonally through a central portion of the device region, wherein the hollow core comprises one of air or dielectric material. The source contact layer can be in electrical contact with the source via the first silicide region and the drain contact layer can be in electrical contact with the drain via a second silicide region.

The transistor structure can include the source, the gate and the drain that are vertically aligned and orthogonal to the plane. The transistor structure can include the second source, the second gate and the second drain that are vertically aligned and orthogonal to the plane.

In some aspects the present solution relates to a gate all around (GAA) transistor structure. The GAA transistor structure can include a stack of layers upon a substrate. The stack of layers can include a first device. The first device can include a first insulation layer separating a source contact layer from a gate contact layer and a second insulation layer separating a drain contact layer from the gate contact layer. The first device can include a device region orthogonal to a plane defined by a surface of at least one of the layers in the stack of layers, the device region comprising a source and drain separated by a channel region that is at least partially surrounded by a gate dielectric interposed between the gate contact layer and the channel region. The first device can include a first region that includes a first silicide formed at a first end of the device region proximal to the source and a second region that includes a second silicide formed at a second end of the device region proximal to the drain. The stack of layers can include a second device. The second device can include a third insulation layer separating a second source contact layer from a second gate contact layer and a fourth insulation layer separating a second drain contact layer from the second gate contact layer. The second device can include a second device region orthogonal to the plane and comprising a second source and a second drain separated by a second channel region that is at least partially surrounded by a second gate dielectric interposed between the second gate contact layer and the second channel region. The second device can include a third region that includes a first germanicide formed at a first end of the second device region proximal to the second source and a fourth region that includes a second germanicide formed at a second end of the second device region proximal to the second drain.

The GAA transistor structure can include the device region that includes doped silicon and the second device region comprises doped germanium. The GAA transistor structure can include the first device and the second device that are vertically aligned. The GAA transistor structure can include the source contact layer that is in electrical contact with the source via the first region and the drain contact layer is in electrical contact with the drain via the second region.

The GAA transistor structure can include the source, the gate and the drain that are vertically aligned and orthogonal to the plane and the second source, the second gate and the second drain are vertically aligned and orthogonal to the plane. The GAA transistor structure can include a hollow core extending orthogonally through a central portion of the device region, wherein the hollow core comprises at least one of air and a dielectric material. The GAA transistor structure can include the source contact layer that is in electrical contact with the source via a first silicide region of the silicide regions and the drain contact layer is in electrical contact with the drain via a second silicide region of the silicide regions.

In some aspects, the present solution relates to a method. The method can include forming a stack of layers upon a substrate. The stack of layers can include a first device and a second device. The first device can include a source contact layer, a gate contact layer with a first insulation layer between the gate contact layer and the source contact layer and a drain contact layer with a second insulation layer between the gate contact layer and the drain contact layer. The method can include forming a device region orthogonal to a plane defined by a surface of at least one of the layers in the stack of layers. A source of the device region and a drain of the device region can be formed. A channel region that is at least partially surrounded by a gate dielectric interposed between the gate contact layer and the channel region to form a gate of the device region can be formed. The channel region can separate the source from the drain. The method can include forming a first region comprising a first silicide at a first end of the device region proximal to the source and a second region comprising the second silicide at a second end of the device region proximal to the drain. The second device of the stack of layers can include a second source contact layer, a second gate contact layer with a third insulation layer between the second gate contact layer and the source contact layer and a second drain contact layer with a fourth insulation layer between the second gate contact layer and the second drain contact layer. The method can include forming a second device region orthogonal to the plane. A second source of the second device region and a second drain of the second device region can be formed. A second channel region that is at least partially surrounded by a second gate dielectric interposed between the second gate contact layer and the second channel region to form a second gate of the second device region can be formed. The second channel region can separate the second source from the second drain. The method can include forming a third region that can include a first germanicide at a first end of the second device region proximal to the second source and a fourth region including a second germanicide at a second end of the second device region proximal to the second drain.

The method can include forming a hollow core extending orthogonally through a central portion of the device region. The hollow core can include one of air or dielectric material. The method can include forming, by the gate contact layer, a ring around the channel region with the gate dielectric interposed between the gate contact layer and the channel region. The device region can include a doped silicon and the first region can include silicide. The device region can include a doped germanium and the first region can include germanicide.

These and other aspects and implementations are described in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the present disclosure can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIGS. 1-9 include cross-sectional and top-down illustrations of an example fabrication flow for manufacturing transistor structures with a dielectric stack and silicide and germanicide formed by SiGe etching, according to some embodiments.

FIGS. 10-14 include cross-sectional and top-down illustrations of an example fabrication flow for manufacturing transistor structures with a metal dielectric stack used to fill metal contact layers, according to some embodiments.

FIGS. 15-22 include cross-sectional and top-down illustrations of an example fabrication flow for manufacturing transistor structures using SiGe-based epitaxially grown layers for enhancing the compatibility of epitaxially grown adjacent Si-based and Ge-based transistor devices, according to some embodiments.

FIGS. 23-26 include cross-sectional and top-down illustrations of an example fabrication flow for manufacturing transistor structures using SiGe-based epitaxially grown layers for enhancing the compatibility of epitaxially grown adjacent Si-based and Ge-based transistor devices, according to some embodiments.

FIG. 27 include cross-sectional and top-down illustrations of an embodiment of an example fabrication flow for manufacturing a transistor structure using separate SiGe layers and separate metals for forming silicide and germanicide regions, according to some embodiments.

FIG. 28 is a flow diagram of an example method for fabricating transistor structures, including Si-based and Ge-based structures with silicide and germanicide regions, in connection with FIGS. 1-27, according to some embodiments.

### DETAILED DESCRIPTION

Reference will now be made to various illustrative embodiments depicted in the drawings, and specific language will be used to describe the same. It will nevertheless be understood that no limitation of the scope of the claims or this disclosure is thereby intended. Alterations and further modifications of the inventive features illustrated herein, and additional applications of the principles of the subject matter illustrated herein, which would be apparent to one of ordinary skill in the relevant art having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

It is understood that apparatuses, systems and devices produced by the structures described herein can be used or find their application in any number of electronic devices utilizing structures and/or circuits described herein, such as for example, controllers, memory chips, systems or process on a chip processors, graphics processing units, central processing units and more. For example, structures and/or circuits described herein can include a part of systems including or utilizing memory, such as any computing systems including for example: computers, phones, servers, cloud computing devices, and any other device or system that utilizes integrated circuit devices.

The embodiments described herein may enable an increased stack height of one or more 3D semiconductor devices. Therefore, a semiconductor substrate can be used, but is not required, and any base layer material (e.g., glass, organic, etc.) may be used instead of a silicon substrate. A base layer, therefore, can be a semiconductor substrate, such as a silicon substrate or any other semiconductor, ceramic, metal or other material substrate.

The process flows described herein can utilize conductive dielectric materials to form NMOS and PMOS devices. As such, the techniques described herein can be used to produce devices that are manufactured, or “stacked” on any existing vertically stacked device or substrate, according to various implementations. The present techniques may improve upon other semiconductor manufacturing techniques by increasing the N height of stacked semiconductor devices, such as transistors, thereby providing high density logic. Although illustrations herein may show an NMOS device arranged over a PMOS device, alternative configurations may include a PMOS device over NMOS device, NMOS device over NMOS device, PMOS device over PMOS device, or other alternative including one or more NMOS devices or PMOS devices for any number of N stacks and in any order or arrangement.

Dielectric materials used herein can be any material or materials having low electrical conductivity, such as for example one millionth of a mho/cm. Dielectric materials can include, for example, silicon dioxide, silicon nitride, nanoporous silica, hydrogensilsesquioxanes (HSQ), Teflon-AF (Polytetrafuoethene or PTFE), Silicon Oxyflouride. Dielectric materials can also include, for example, ceramics, glass, mica, organic and oxides of various metals.

High-k dielectric, also referred to as high-k material, can refer to any material with a higher dielectric constant as compared to the silicon dioxide. For example, high-k dielectric can include hafnium silicate, zirconium silicate, hafnium dioxide, zirconium dioxide, and others.

Various metals, such as gate metal and the source/drain metal, can be used herein and can include any metal or any electrically conductive material. For example, metals used in the present solution can include aluminum, copper, titanium, ruthenium, tungsten, silver, gold or any other metal. For the purposes of the present solution, in addition to the metals, source/drain metals or gate metals can also include other electrically conductive materials, such as highly doped semiconductors, for example.

The present solution can also utilize 2D materials for forming transistor channels. 2D materials can include, for example, but are not limited to, WS2, WSe2, WTe2, MoS2, MoSe2, MoTe2, HfS2, ZrS2, and TiS2, GaSe, InSe, phosphorene, and other similar materials. These materials can be deposited by an atomic layer deposition (ALD) process and may be about 5-15 angstroms thick, the thinness lending to their name— 2D material. 2D material layer can, depending on the material and design, have a broader range of thicknesses, such as between 0.2 nm and 3 nm, for example. 2D materials may be annealed during or after the device formation process to recrystallize or grow the crystals and thereby improve electrical characteristics. 2D materials, for example, can be electrically conductive.

Additionally or alternatively, the channels may comprise one or more semiconductive-behaving oxide materials, which may be formed using certain elements that, when combined with oxygen, form a new material that exhibits semiconductive behavior. For example, the semiconductive behaving material can be “turned off” and can have a low or practically no off-state leakage current, and can be “turned on” and become highly conductive when voltage is applied. Example materials to create an n-type channel for example include, but are not limited to, In₂O₃, SnO₂, In GaZnO, and ZnO. Example materials that can be used to create a p-type channel may be formed utilizing, for example, SnO. These materials may be further doped to improve the electrical characteristics. These materials may also be referred to as conductive oxides or semiconductive behaving oxides for the purposes of this discussion.

As 2D materials can have a very large mobility, they can be herein described as one embodiment, however it is to be appreciated that other non-epitaxially grown materials can be utilized. Since a 2D material can be precisely deposited on an insulative sheet, this can enable a very low Dt integration build of horizontal nanosheets with high performance. Advantageously, any base substrate material can be utilized as no epitaxial growth is required and the base substrate can be removed for further stacking of the devices.

The order of description or fabrication steps performed or described herein has been presented for clarity sake and as an example. The fabrication steps described herein can be performed in any suitable order. Additionally, although each of the different features, techniques, configurations described herein may be described in different places of this disclosure, it is intended that each of the concepts can be executed independently of each other or in combination with each other. Accordingly, the solutions described herein can be embodied and viewed in many different ways.

Reference will now be made to the Figures, which for the convenience of visualizing the 3D semiconductor fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections, and they should not be considered limiting to the scope of the claims. Conversely, when example illustrations do not show electrical connections to components that are electrically contacted, it is understood that such electrical connections can be made as understood by a person of ordinary skill.

Although the Figures and aspects of the disclosure may show or describe devices herein as having a particular shape, it should be understood that such shapes, whether of the structures or features, are used as examples of the present solution and are merely illustrative and should not be considered limiting to the scope of the techniques described herein. For example, although most of the Figures show various layers in a rectangular shaped configuration, other shapes are also contemplated, and indeed the techniques described herein may be implemented in any shape or geometry. In addition, examples in which two transistors or devices are shown stacked on top of one another are shown for illustrative purposes only, and for the purposes of simplicity. Indeed, the techniques described herein may provide for one to any number N stacked devices. Further, although the devices fabricated using these techniques are shown as transistors, it should be understood that any type of electronic device may be manufactured using such techniques, including but not limited to transistors, variable resistors, resistors, capacitors, memory components, logic gates and components and any other components known or used in the art.

Despite the fact that illustrated embodiments for simplicity and brevity show examples of only a single or double transistor structures being formed using the techniques of the present solution, any number of transistors can be formed above and beside the transistor structures illustrated in examples illustrated, such as may be desired for forming a 3D array of devices.

Techniques described herein can provide structures that can be manufactured using methods discussed herein for fabricating 3D microelectronic devices, which can include stand-alone devices or vertical transistors, including 3D sequential circuit builds. Techniques described herein can enable ultra-dense 3D design with method of integration of high performance VFETs. For instance, the present solution can include a fabrication method in which a metal gate electrode of a transistor is formed early in the process as a support or a pillar to hold or carry multiple adjacent materials that can be applied thereon while forming the transistor. In some implementations, as few as only three lithographic masks can be utilized to create an entire array of VFET structures using the gate electrode support structure to provide various instances of self-aligned directional etching.

This disclosure can allow for higher density circuits to be produced at reduced cost. These circuits can include transistor structures in which chemical compounds formed at or near interface of metals and semiconductors, such as silicides or germanicides, can improve electrical properties of the circuits. The present solution provides structures and techniques for fabricating a plurality of 3D semiconductor devices in a 3D stack which could include n-type, p-type, or a combination of n-type and p-type devices. For example, examples discussed herein show a mix of n-type and p-type transistors being fabricated together, where silicon is used as an example material used for NMOS transistors and germanium as an example material for PMOS, with an understanding that other semiconductors can be used, as well. The examples illustrated herein further show silicide or germanicide regions formed at distal ends of the semiconductor device region which can be oriented vertically so as to conduct current in a vertical, or z-direction, relative to the major surface in or upon which the devices are formed, such as the surface of the illustrated silicon substrate or the material layers in which the devices are formed. Separate silicide or germanicide regions can be formed at or near source, drain and/or gate contacts independently for optimum high mobility and conductivity.

The present disclosure provides one or more example device structures and their corresponding process flows for fabricating such silicon (Si) based and germanium (Ge) based example devices, which in the illustrated embodiments are transistor devices, although it is understood that other devices or circuits are also contemplated. In one example, devices can be fabricated with a process flow in which doped Si, such as n-Si, and/or doped Ge, such as p-Ge, can be used to form n-type and p-type transistor devices, which can include the corresponding silicide and/or germanicide regions at or near source, drain and/or gate contact interfaces. Fabricated devices can be electrically isolated or separated from each other in the vertical orientation using either an air gap or solid fill dielectric. In one example, metal dielectric stack can be used instead of dielectric etch to fill up the metal contact layers either keeping air gap inside the devices or filling the devices with a dielectric. In another example, separate epitaxially grown layers of Silicon-Germanium alloy materials, such as SiₓGe₁₋ₓ and Si_{y}Ge_{1-y}, can be used for enhancing compatibility of epitaxial growth of adjacent n-Si and p-Ge devices. This approach can allow for deposition of separate metals to form silicide and germanicide regions in devices. The present solution can also use separate SiGe layers for enhancing the compatibility of epitaxial growth of n-Si and p-Ge devices, allowing to deposit separate metals to form silicide and germanicide regions in devices in devices in which air gaps or solid dielectric filling can be used for electrical isolation. The present solution can also use form n-Si and p-Ge based without silicide and germanicide regions.

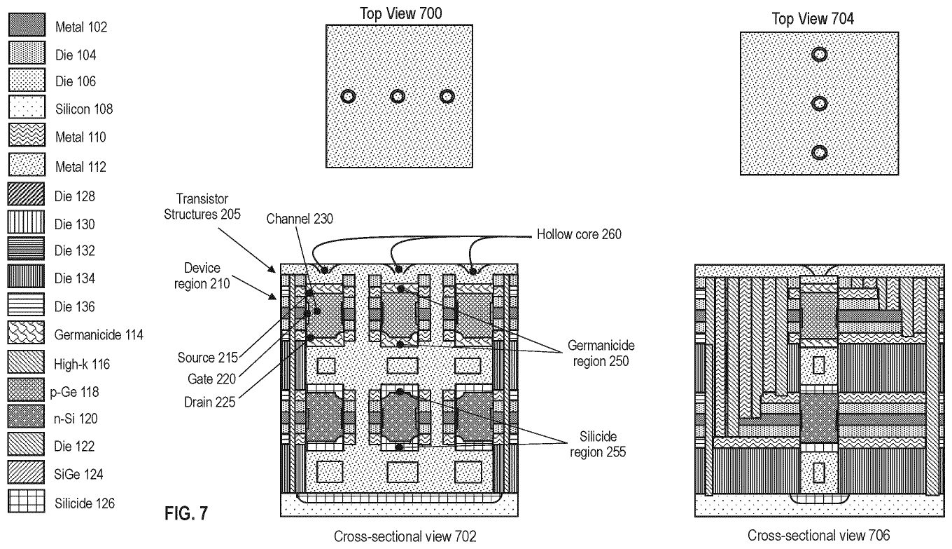

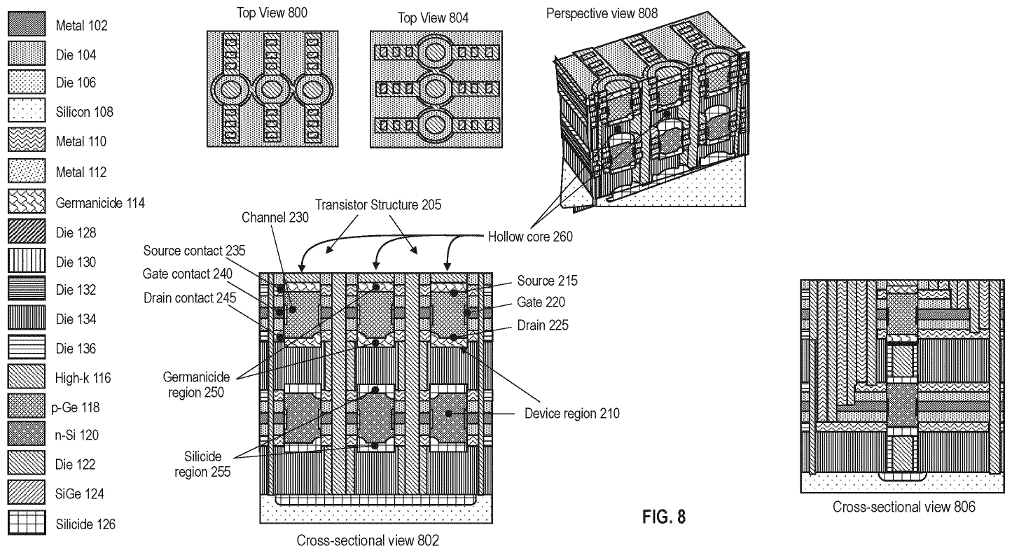

Prior to describing the fabrication steps for manufacturing the present solution, it may be useful to first briefly overview an example of transistor fabricated in accordance with the methods and techniques of the present solution. Illustrated in FIG. 7 and FIG. 8 are examples of a stacked (e.g., vertical) and lateral (horizontal) array of vertically oriented transistor structures 205 (e.g., VFETs). Transistor structures 205, also referred to as transistors 205, can be fabricated using n-Si 120 material for an NMOS configuration, as shown in the lower row of transistor structures 205 of FIGS. 7-8, whereas the upper row includes transistor structures 205 include device regions 210 fabricated using p-Ge 118 material for the PMOS configuration. Each transistor structure 205 can include a source 215 and its corresponding source contact 235, a gate 220 and its corresponding gate contact 240 and a drain 225 and its corresponding drain contact 245. Each transistor structure can also include a channel 230 and a hollow core 260 opening that can run vertically through the center of the device region 210 and extend above and below the device region 210. Device regions 210 fabricated using n-type doped silicon (e.g., n-Si 120) can include a silicide region 255 formed at or near the interface of the n-Si 120 and metal contact materials. Similarly, device regions 210 fabricated using p-type doped germanium (e.g., p-Ge 118) can include germanicide 250 regions formed at or near the interface of the p-Ge 118 and metal contact materials.

As will be discussed in a greater detail in the figures below, the silicide regions 255 and germanicide regions 250 can include chemical compounds that can be formed within, between or near a semiconductor material, such as n-Si 120 or p-Ge 118, and a metal. For example, silicide region 255 can be formed when a layer of metal that is suitable for forming a binary compound with silicon upon annealing, is in a physical contact with Si material and is exposed to a temperature level sufficiently high (e.g., in an annealing process) to form the silicide region at or near the interface of the Si and the metal. Similarly, germanicide region 250 can be formed when a layer of metal that is suitable for forming a binary compound with germanium upon annealing, is in a physical contact with Ge material and is exposed to a temperature level sufficiently high (e.g., in an annealing process) to form the germanicide region at or near the interface of the Ge and the metal. While illustrated embodiments show only Si-based and Ge-based chemical compounds (e.g., silicide 126 and germanicide 114) to improve electrical properties of transistor structure 205, it is understood that similar compounds can be formed using other semiconductor and metal materials, including for example using any combination of materials discussed herein.

Although FIGS. 7-8 illustrate only six transistors 205, shown in vertical and horizontal arrays, it is understood that these and other arrays can extend in the vertical and horizontal directions with as many transistors 205 as is required for a given application and the arrays need not be periodic or have a regular pattern. Each transistor 205 can be formed within and/or include a stack of layers to form the source, gate and drain contacts, 235, 240 and 245, respectively using their corresponding metal material layers (e.g., 110, 102) that can be separated by dielectric layers (e.g., 104, 106 or other dielectrics). Each device region 210 can include its own source 215, channel 230, and drain 225 which can be provided as a vertical structure such that the current travels in a direction generally orthogonal to the major plane of the substrate (e.g., silicon 108). Silicide or germanicide regions (e.g., 250, 255) can include silicide 126 material, or germanicide 114 material, respectively. Silicide and germanicide regions 255 and 250 can be provided at least at or near the source 215 and drain 225 ends of the device regions 210 and may be partially or fully interposed between the source and drain contacts 235 and 245 and the device region 210. As will be further discussed in the Figures below, transistors 205 can include a hollow core 260 in which a portion of the device region 210 either remains a hollow cavity (e.g., filled with air) or is replaced with a dielectric material along the length of the vertical device region 210, which can improve electrical characteristics of the transistors 205.

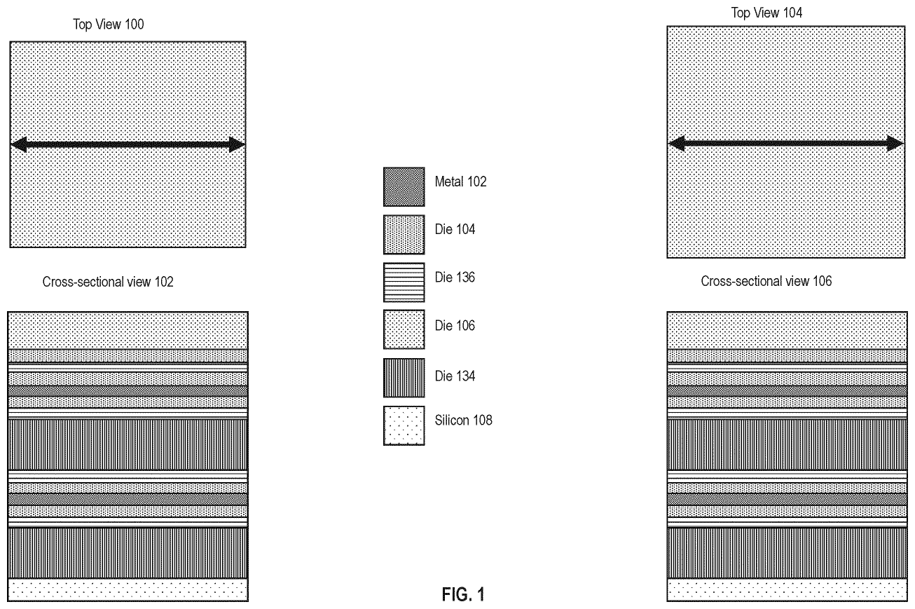

Referring now to FIG. 1, cross-sectional views 102 and 106 and top views 100 and 104 are illustrated in which the cross-sectional views 102 and 106 represent cross-sections taken along the double-sided arrows shown in top views 100 and 104. As shown in FIG. 1, on top of silicon or other substrate, a series of layers is formed comprising different dielectric layers or materials, such as dielectric 104, dielectric 136, dielectric 106 and dielectric 134. These dielectric materials (e.g., 104, 136, 106 and 134) may be same or different dielectric materials, depending on the design. In the illustrated example, the use of different dielectric materials can allow for selectivity during processing or may be utilized to achieve desired device characteristics. According to one implementation, a first dielectric, dielectric 134 (e.g., die 134), can be deposited or formed on a semiconductor substrate, e.g., silicon 108, although any substrate can be used instead of silicon. Next, two more dielectric layers, dielectrics 136 and 104 (e.g., in the figures identified as die 136 and die 104) can be deposited or formed on top of dielectric 134. A metal 102 layer can then be deposited or formed upon dielectric 104 followed by layers of dielectric 104, dielectric 136 formed above the metal 102 layer, which can be followed by a layer of dielectric 134 on top of dielectric 136. A similar stack of layers can be formed thereupon including, dielectrics 136 and 104, metal 102, dielectric 104, dielectric 136, and final dielectric 104, as shown. Finally at the top a thicker dielectric 106 cap layer if formed above the uppermost layer. It is understood that these dielectrics can include the same or different materials, depending on the fabrication preferences.

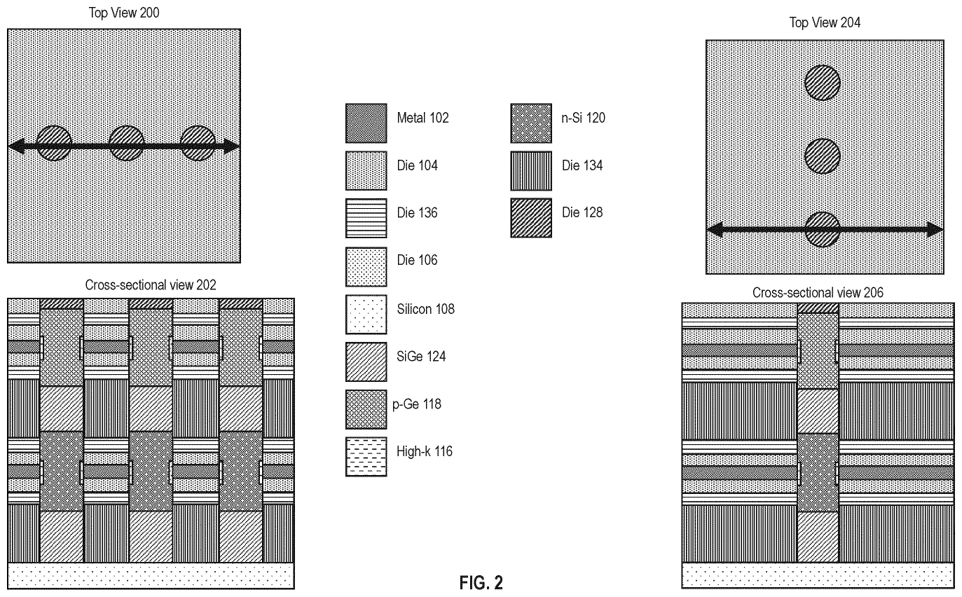

Referring now to FIG. 2, cross-sectional views 202 and 206 and top views 200 and 204 are illustrated in which the cross-sectional views 202 and 206 represent cross-sections taken along the double-sided arrows shown in top views 200 and 204. As shown in FIG. 2, after directional etching of the stack of layers shown in FIG. 1, vias, cavities or openings can be formed to create the space in which device regions 210 are to be formed. Device regions 210 can be formed using n-Si 120 and p-Ge 118 materials by epitaxially growing SiGe 124, n-Si 120, SiGe 124 and then p-Ge 118 inside of the openings and starting from the silicon 108 substrate. Fabrication methodologies and techniques that can be used to form device regions 210 and other features discussed herein are disclosed at least in U.S. patent application Ser. No. 17/558,490, titled Method of Making of Plurality of 3D vertical Logic Elements Integrated with 3D memory, as well as U.S. patent application Ser. No. 17/721,124, titled Formation of High Density 3D Circuits with Enhanced 3D Conductivity, both of which are incorporated by reference in their entirety. ALD deposition of high-k 116 dielectric followed by its directional etch can be implemented to create a gate dielectric (e.g., gate oxide formation). Finally a dielectric cap layer (e.g., dielectric 128) can formed to protect the structure. A CMP process can then be used to planarize dielectric 128 and dielectric 106.

While illustrated examples show transistor structures 205 fabricated using Si and Ge materials, it will be appreciated by those skilled in the art that other materials, or mix of materials, may be used in place of the Si and Ge. For example, the transistors 205 can include only Silicon, only Germanium, especially if only p type or only n type devices are to be fabricated, or any combination of Si and Ge materials. Moreover, materials such as semiconductive behaving oxide materials or 2D materials can be utilized to form channels 230 and/or whole device regions within the openings, using techniques and methodologies, such as those disclosed by the inventors in at least U.S. patent application Ser. No. 17/578,412, titled 2D Material to Integrate 3D Horizontal Nanosheets Using a Carrier Nanosheet, as well as U.S. patent application Ser. No. 17/672,488, titled Silicon Nanosheet and 2D Parallel Channel Vertical FET Design with Wafer Transfer Technology and Metal First Approach, both of which are incorporated by reference in their entirety.

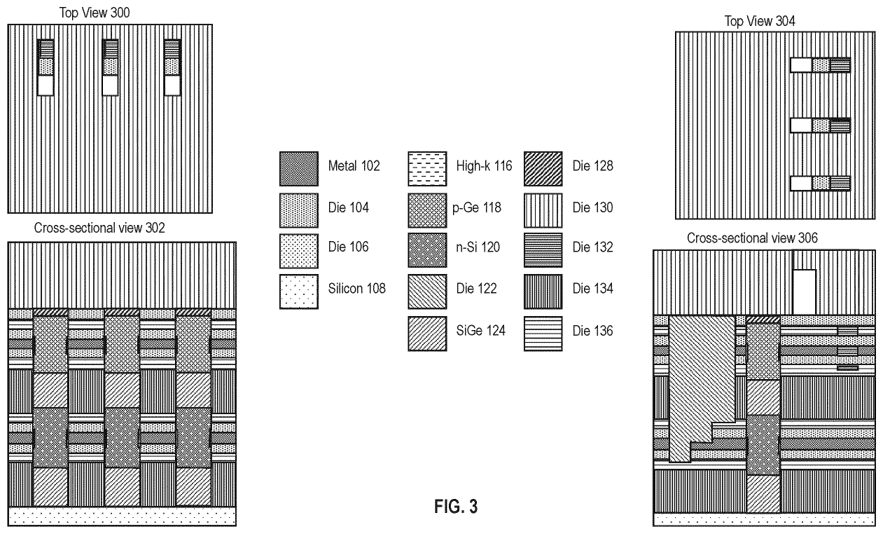

Referring now to FIG. 3, cross-sectional views 302 and 306 and top views 300 and 304 are illustrated, in which isotropic dielectric 130 can be deposited or formed. This can be followed by directional etch of dielectric 130 using a photo resist mask, which may subsequently be removed. Then using the dielectric 130 as a mask defining an opening, underlying layers aligned with the opening can be directionally etched to reach to the desired contact layer for n-Si 120 and p-Ge 118.

The steps of masking and etching can be repeated to create an opening to metal 102 of the lower sub-stack (PMOS device), and also to create an opening to the dielectric 136 (e.g., die 136) layers of the lower sub-stack. The openings can then be filled with one or more dielectric materials, such as dielectric 122. This process may involve an overfill that can be followed by chemical-mechanical polishing (CMP). Then, another etch mask can be used to repeat the process for n-silicon contacts at a different radial direction from the device region as compared to contacts for p-germanium device. Therefore, transistor structure 205 at different height levels (e.g., upper and lower, as for example illustrated in FIGS. 7-8) can be vertically aligned with each other, or can be not aligned, and offset from each other to allow for different metal contact via layout for accessing transistors 205 buried within the stack.

Dielectric 132 can be used to protect the metal layers and dielectric 136 layers during other directional etching as is described, for example, in the above-stated incorporated references. Finally, the openings are filled by dielectric 122 and a CMP process can be used to planarize the structure. FIG. 3, and particularly cross-sectional view 306, shows top and side views after filling with dielectric 122, which fills a staircase profile with the layer stack for accessing source, gate and drain layers from different spatial locations on a top of the substrate.

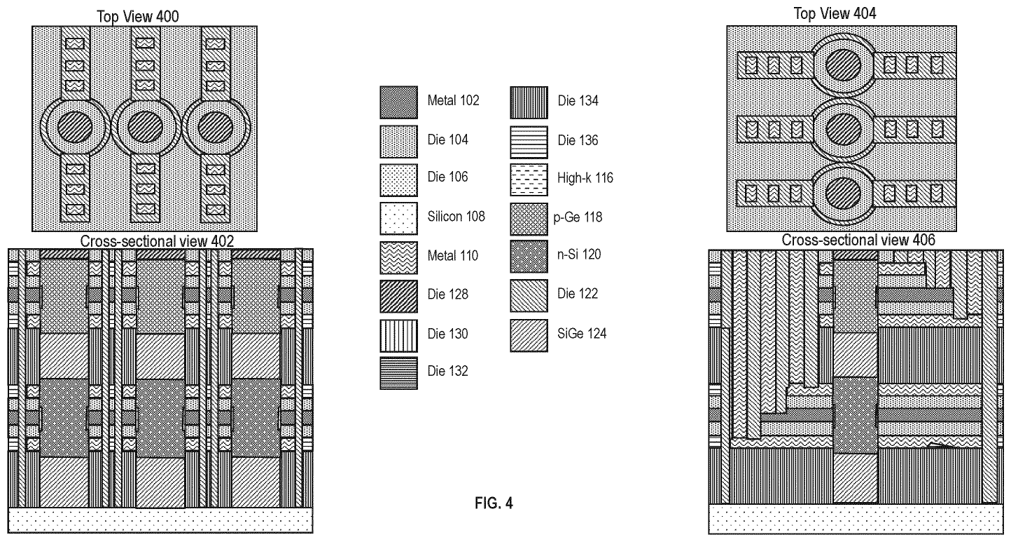

Referring now to FIG. 4, cross-sectional views 402 and b and top views 400 and 404 are illustrated in which a separate etch masked can be formed and a directional etch can be executed to etch all layer of the layer stack until uncovering the underlying silicon 108 layer. This can separate each vertical device region 210 stack from other devices as multiple devices can make use of the same layer stack that can include metal layers for multiple layers or levels of transistors 205.

The opening(s) created by the isolation etch can be filled with dielectric 122 and planarized. A patterning mask can be formed for contact etching. This can etch vertical openings within dielectric 122, landing or stopping on metal 102 and dielectric 136 layers. With dielectric 136 layer segments accessible, an isotropic etch can be executed to remove accessible portions of dielectric 136. This can remove the horizontal portion of dielectric 136 until reaching the vertical device structures 210. An ALD layer or electroplating of metal 110 can be executed, which can enable growing thick layers of metal 110 irrespective of bending or angles in the openings formed for metallization. The openings are thereby filled with metal 110, followed by CMP planarization.

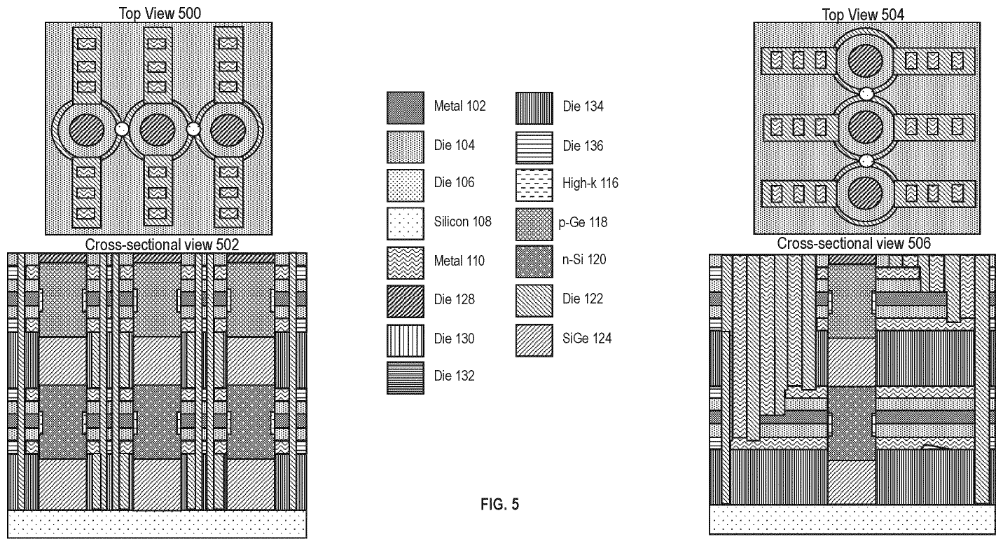

Referring now to FIG. 5, cross-sectional views 502 and 506 and top views 500 and 504 are illustrated in which a trench can be patterned on the junction point of two consecutive devices and directional etch of the dielectric layer(s) can be performed to reach to the silicon substrate. After stripping the PR mask used to define the trench, dielectric 134 is wet etched in order to access the SiGe 124.

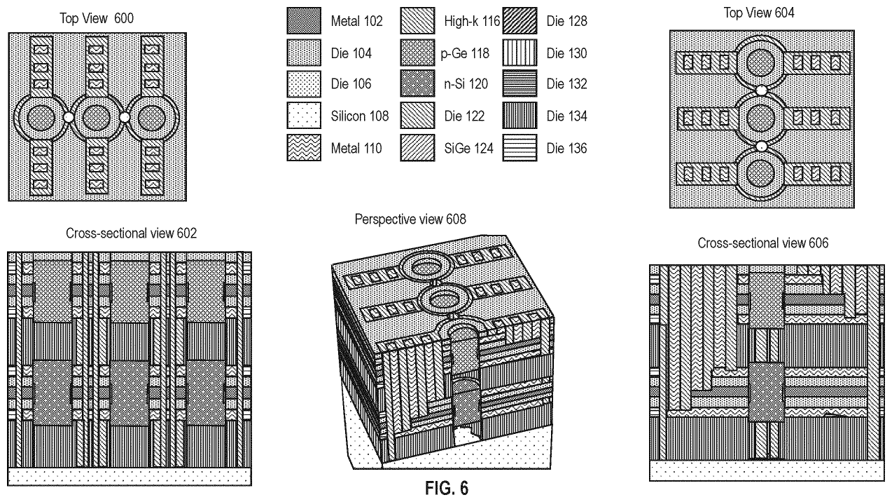

Referring now to FIG. 6, cross-sectional views 602 and 606 and top views 600 and 604 are illustrated in which SiGe 124 layers can be wet etched followed by the etching of dielectric 128 above the uppermost device region.

Referring now to FIG. 7, cross-sectional views 702 and 706 and top views 700 and 704 are illustrated in which a metal 112 can be formed using ALD or other suitable techniques. Example materials for metal 112, as well as other metals discussed herein, can include Ru, W, Ti, Ni, Cu, or other suitable material. The transistor structures 205 can then be annealed by being baked or otherwise exposed to a sufficiently high temperature for a sufficient amount of time (e.g. annealing process) in order to form silicide regions 255 with silicide 126 at or near the intersections between the n-Si 120 and the metal (e.g., 110). The same or a different anneal can be performed to create germanicide region 250 with germanicide 114 at or near the intersections of the metal (e.g., 110) and p-Ge 118. The silicide and germanicide regions 250 and 255 can be formed on the corresponding semiconductor layers of the device regions near the metal structures (e.g., 102, 110, 112). The silicide and germanicide regions 250/255 can enhance the electrical properties between the device regions 210 and the S/D contact metal layers forming the source and drain contacts 235/245 adjacent to the device regions 210. Silicide 126 may additionally or alternatively be formed from the interaction of the S/D contacts 235/245 and the device region 210 and in either case may extend such that the silicide 126 (or germanicide 114) is partially or fully interposed between the S/D contacts 235/245 and the device region 210 (e.g., n-Si 120 or p-Ge 118 materials).

Referring now to FIG. 8, cross-sectional views 802 and 806, top views 800 and 804 and the perspective view 808 are illustrated in which metal 112 layer can be removed through a wet etch or other suitable removal process followed by CVD deposition of more dielectric 122 and CMP to thereby fill the trenches (e.g., hollow core 260). In this embodiment, air gaps may remain between stacked devices as a form of electrical insulation between the devices.

As illustrated in FIG. 8, the present solution can allow for a structure or fabrication of multiple levels of arrays of devices, such as transistor structures 205. Transistor structures 205 can include device regions 210 formed with epitaxially grown doped and/or not doped semiconductor materials. Device regions 210 can include one or more channels 230, which can be formed using the doped and/or un-doped epitaxially grown material (e.g., n-Si 120, p-Ge 118) or any other techniques, such as 2D materials, nanosheets and similar structures that can be disposed vertically instead of the illustrated n-Si 120 or p-Ge 118 materials. Device regions 210 can include source 215 in electrical contact with a source contact 235, a drain 225 in electrical contact with a drain contact 245 and a gate 220 in electrical contact with gate contact 240. Source 215, gate 220 and drain 225 can be vertically aligned, and can be in any orientation, including source or drain at the top or the bottom. At the distal ends of the device regions 210 (e.g., the source end or the drain end), chemical compound regions for improving electrical properties of the transistors 205 can be formed, including for example silicide region 225 and/or germanicide region 250. As shown in FIG. 8, transistors 205 can be electrically insulated from each other with air gaps disposed been them.

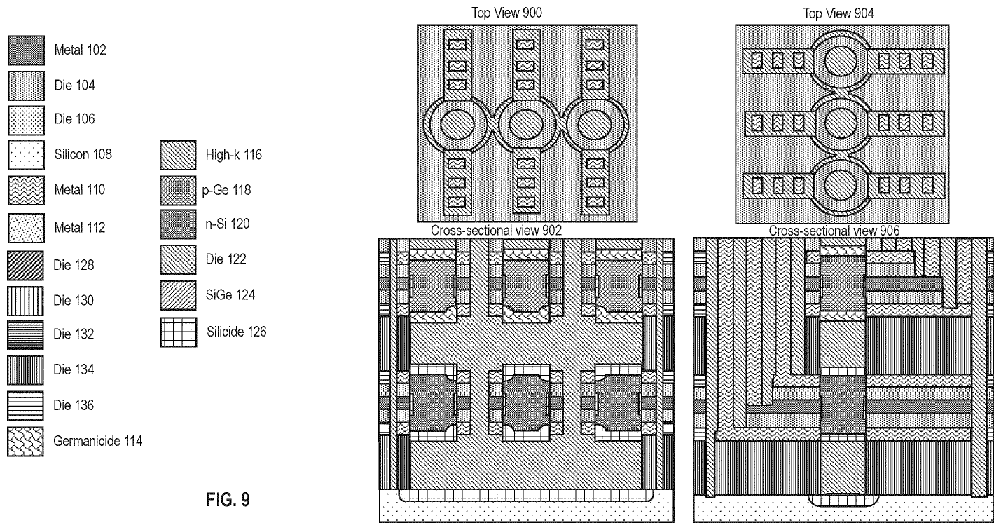

As an alternative to the air gap in FIG. 8, as shown in FIG. 9, including its cross-sectional views 902 and 906 and top views 900 and 904, the entire cavity formed through the trench etched out in connection with FIG. 9, can be filled with a dielectric material, such as dielectric 122. Dielectric 122 can be CVD deposited to fill the air gaps and thereby provide electrical insulation between the transistor structures 205.

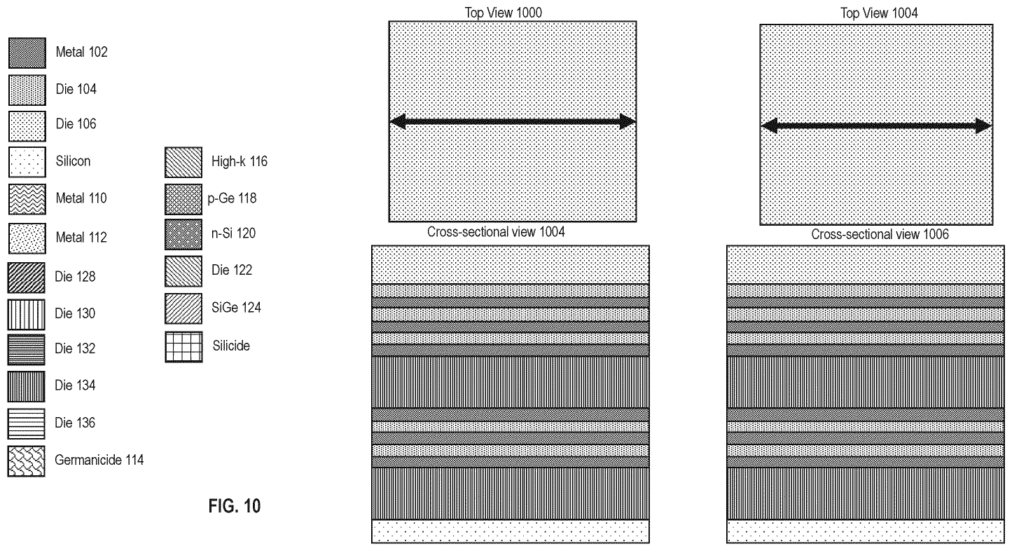

Referring now to FIG. 10, cross-sectional views 1002 and 1006 and top views 1000 and 1004 are illustrated in a similar material layer structure as shown in FIG. 1 is illustrated, with the exception that the initial stack in FIG. 10 includes metal contact layers for the S/D contacts 235/245 thereby eliminating the need to remove dielectric layers and replace them with the conductive materials as shown through the steps described with regard to FIGS. 3 and 4.

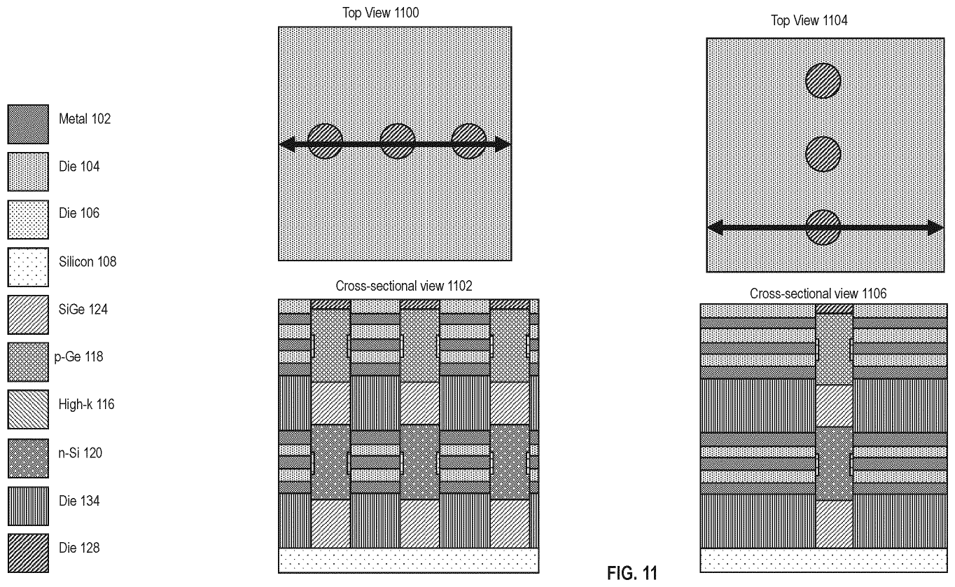

Referring now to FIG. 11, cross-sectional views 1102 and 1106 and top views 1100 and 1104 are illustrated in which same steps as discussed in connection with FIG. 2 can be implemented, but in this case using the material stack with metal 102 replacing dielectric 136 layers. The resultant stack layer includes three metal 102 layers or lines separated by dielectric 104. The regions in between different levels of transistor structures 205 (e.g., upper and lower) can include dielectric 134 layers that are thicker than dielectric 136 layers to allow for electrical insulation between the devices in the vertical direction.

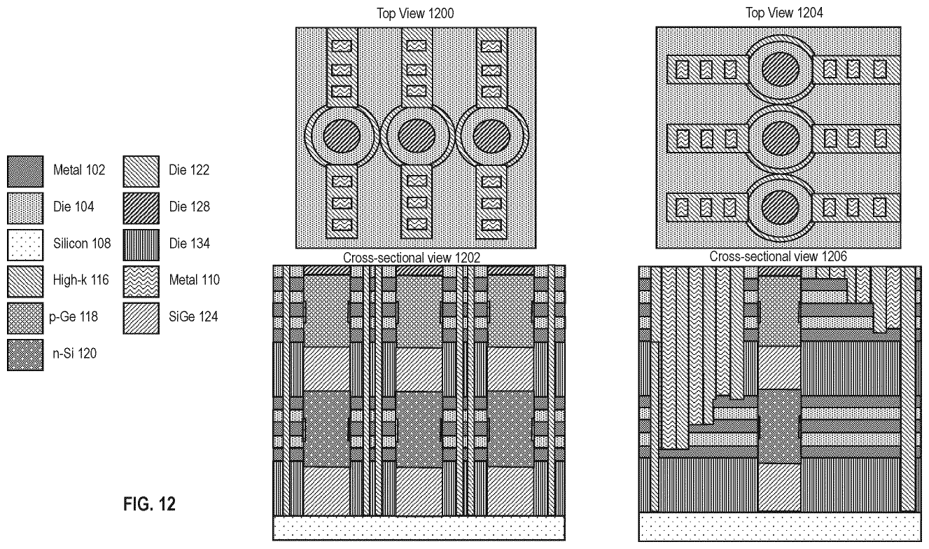

Referring now to FIG. 12, cross-sectional views 1202 and 1206 and top views 1200 and 1204 are illustrated in which same steps as discussed in connection with FIG. 4 can be implemented, but in this case using the material stack with metal 102 from FIG. 10.

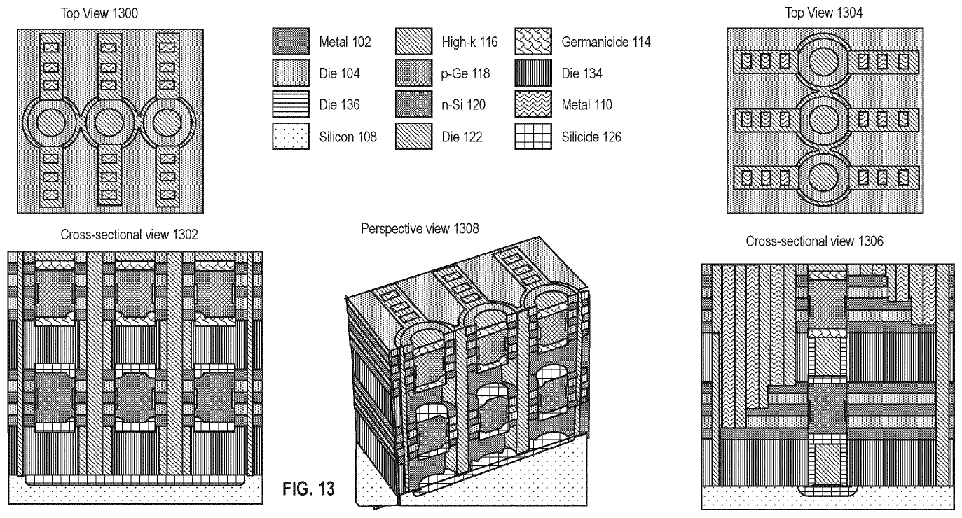

Referring now to FIG. 13, cross-sectional views 1302, 1306 and 1308 and top views 1300 and 1304 are illustrated in which same steps as discussed in connection with FIG. 8 can be implemented, but in this case using the material stack with metal 102. As a result, transistor structures 205 with air gaps in between can be formed.

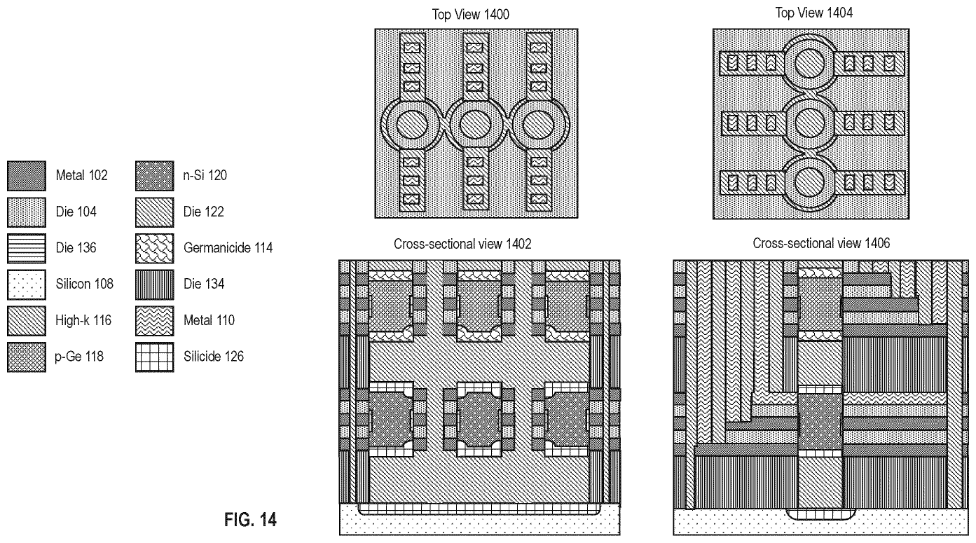

Referring now to FIG. 14, cross-sectional views 1402 and 1406 and top views 1200 and 1204 are illustrated in which same steps as discussed in connection with FIG. 9 can be implemented, but in this case using the material stack with metal 102. As a result, transistor structures 205 with dielectric filling in between them can be formed. In short, FIG. 14 shows a variation in which a portion of the device region 210 is removed and replaced with a dielectric. This variation can apply to any other embodiments including those shown in FIGS. 8-9.

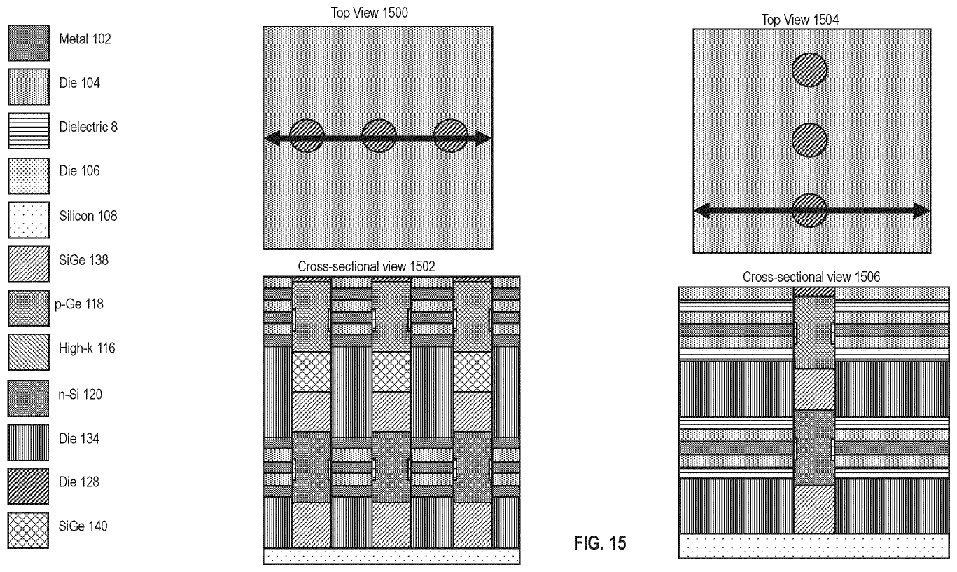

Referring now to FIGS. 15-20, two separate SiGe alloy epitaxially grown layers can be used for enhancing the compatibility with epitaxially grown n-Si 120 and p-Ge 118 in the adjacent device regions 210. This approach can enable deposition of separate metals that allow forming silicide regions 255 or germanicide regions 250 that are configured or tailored to the particular combination of the semiconductor material (e.g., n-Si 120 or p-Ge 118) and the metal material used.

FIGS. 15-22 show an implementation in which different SiGe alloys are used, such as SiₓGe₁₋ₓ, which can be referred to as SiGe 138, and/or Si_{y},Ge_{1-y}, which can be referred to as SiGe 140. SiGe 138 and SiGe 140 selective epi grown layers can be used to improve or fine tune the compatibility of epi-growth of adjacent n-Si 120 and p-Ge 118 devices. This stack enables deposition of separate and/or different metals on each device region 210, which can form optimized silicide regions 255 and/or germanicide regions 250 for source 215 and drain 225 designs utilizing different metal S/D contacts 235/245. The metal dielectric stack concept is shown as one example, but variations described herein for other embodiments may also be applied and contemplated.

Referring now to FIG. 15, cross-sectional views 1502 and 1506 and top views 1500 and 1504 are illustrated in which, after the device growth strategy explained in FIG. 2 is implanted, n-Si and p-Ge device regions 210 can be been grown in the openings. However, while forming SiGe epitaxially grown layers in between device regions 210, a second SiGe (e.g., SiGe 140) with a different mole fraction than the first SiGe (e.g., SiGe 138) can be grown on top before epitaxially growing p-Ge 118.

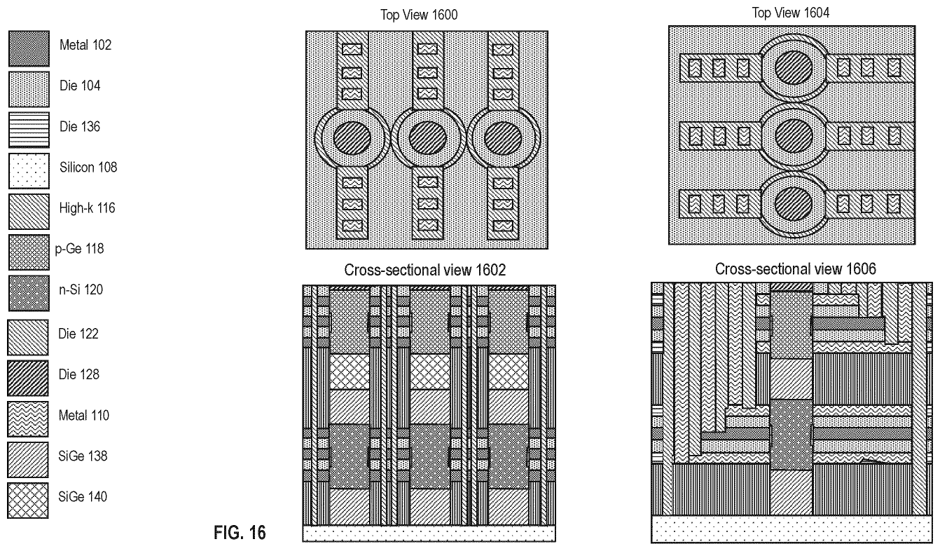

Referring now to FIG. 16, cross-sectional views 1602 and 1606 and top views 1600 and 1604 are illustrated in which similar fabrication steps as discussed in connection with FIG. 4, but in this instance we utilize two different SiGe mole fractions (e.g., SiGe 138 and SiGe 140).

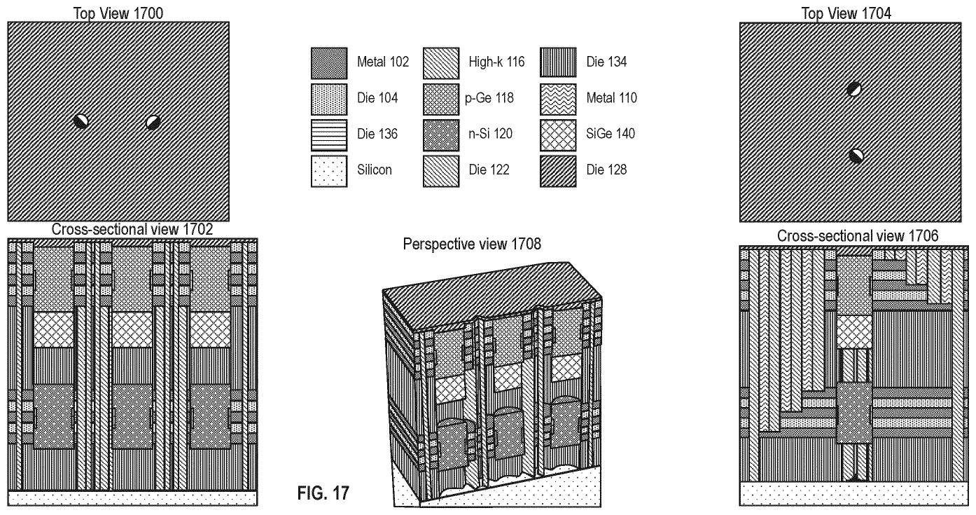

Referring now to FIG. 17, cross-sectional views 1702 and 1706 and top views 1700 and 1704 and perspective view 1708 are illustrated in which fabrication steps same or similar to those in FIGS. 5-6 are implemented, to etch only the SiGe material with Si mole fraction ‘x’ (e.g., SiGe 138). This can be done through the SiGe 140 opening drilled through the center of material column structure, such as SiGe 140 material features herein, as discussed for example in the above-discussed incorporated references.

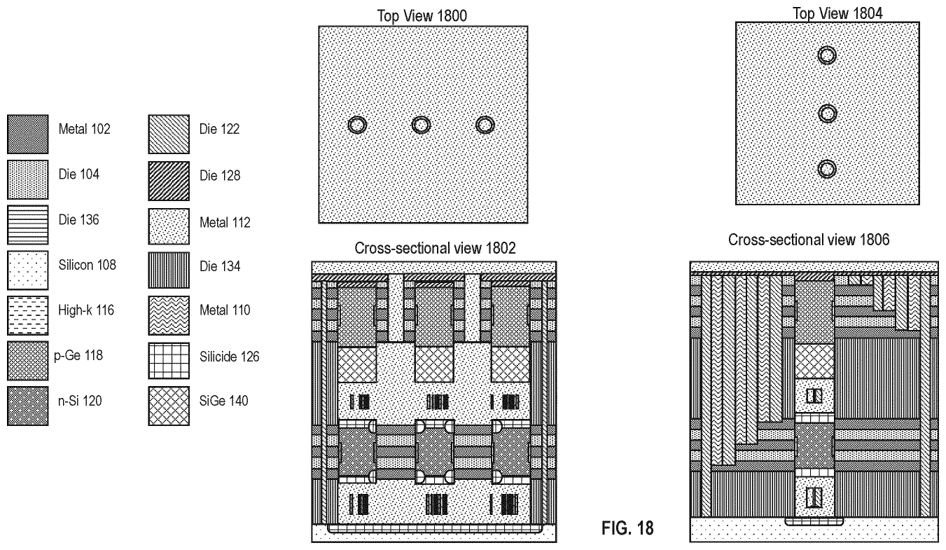

Referring now to FIG. 18, cross-sectional views 1802 and 1806 and top views 1800 and 1804 are illustrated in which fabrication steps similar to those discussed in connection with FIGS. 7-8 are implemented, but in this instance they are done with different SiGe mole fraction materials. A silicide region 255 can be formed with metal 112 and n-Si 120 using SiGe with mole fraction “x” (e.g., 138), while SiGe with Si mole fraction ‘y’ can protect the Ge from alloying with metals.

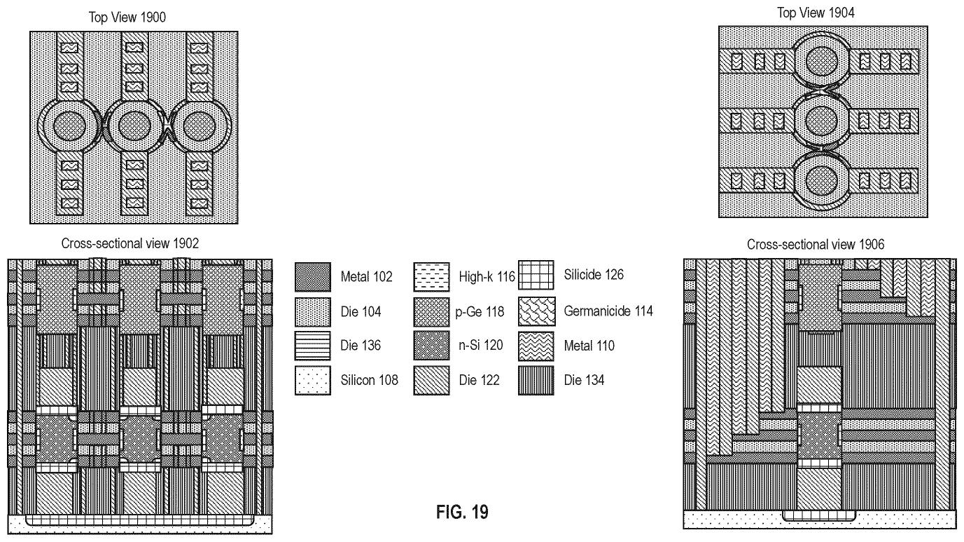

Referring now to FIG. 19, cross-sectional views 1902 and 1906 and top views 1900 and 1904 are illustrated in which wet etching of metal 112 and deposit fill by dielectric 122 can be implemented, followed by a CMP. This can be followed by similar fabrication steps as those discussed in FIG. 17 to etch dielectric 122 and dielectric 134. At this stage we can etch the SiGe with Si mole fraction ‘y’ (e.g., SiGe 140), as well as dielectric 128 to open the top surface of the p-Ge 118 region.

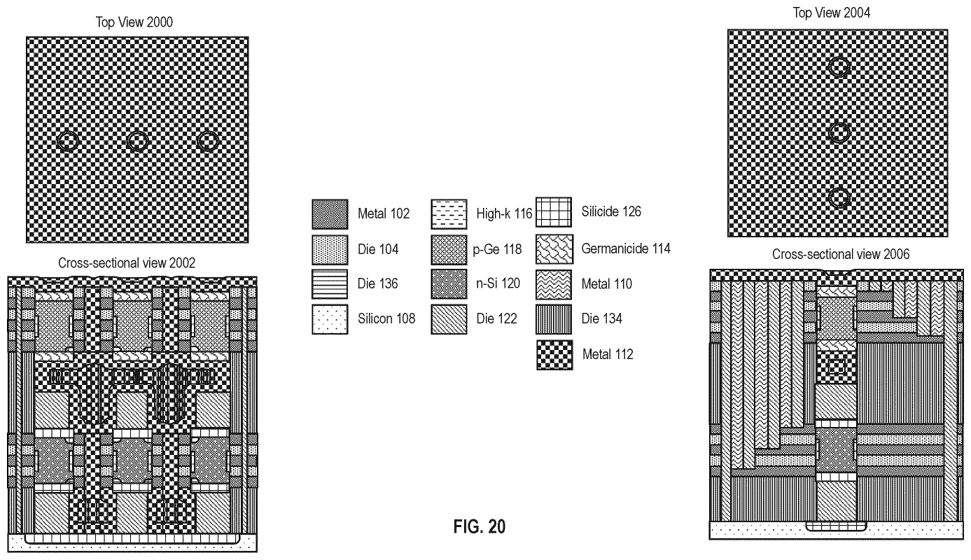

Referring now to FIG. 20, cross-sectional views 2002 and 2006 and top views 2000 and 2004 are illustrated in which ALD deposition of metal 112 is implemented. Then, annealing can be done to form germanicide 114 and the corresponding germanicide region 250.

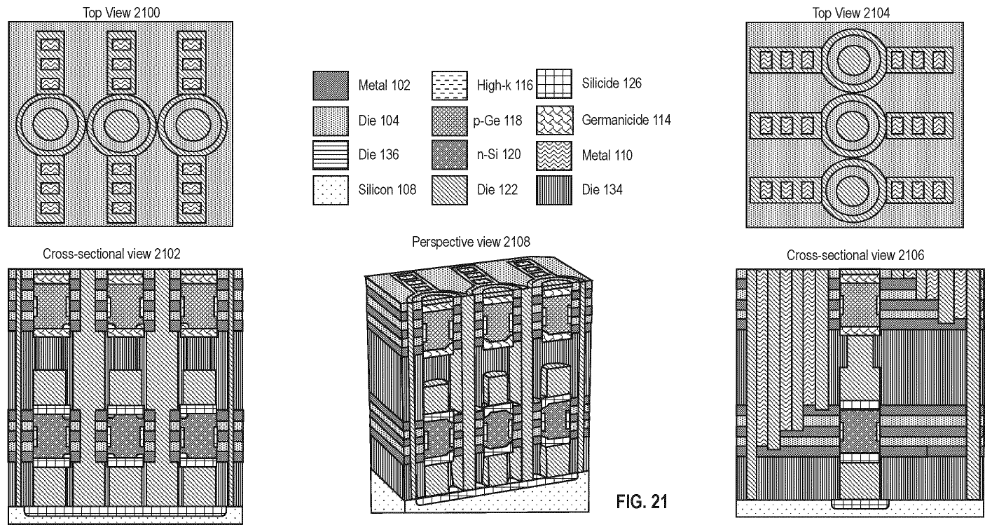

Referring now to FIG. 21, cross-sectional views 2102 and 2106, top views 2100 and 2104 and perspective view 2108 are illustrated in which wet etching of metal 112 can be implemented along with a CVD deposition of dielectric 122 and a CMP. This can result in a structure in which an air gap remains between adjacent stacked transistor structures 205, for insulation, similar to the one discussed in FIG. 8.

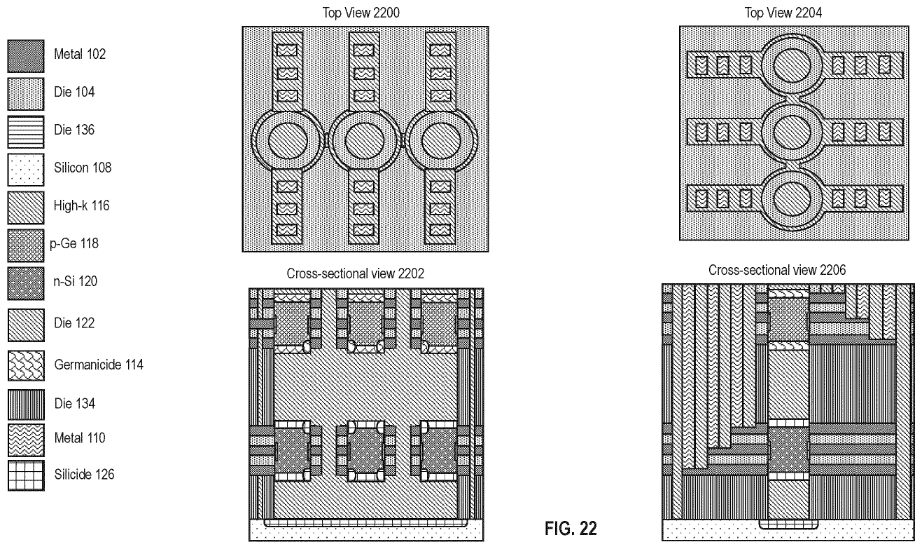

Referring now to FIG. 22, cross-sectional views 2202 and 2206 and top views 2200 and 2204 are illustrated in which, as an alternative to air gap electrical insulation, dielectric 122 can be deposited, followed by a CMP, similar to the way was done in connection with FIG. 9. Following dielectric 122 fill, no air gap may remain in the structure.

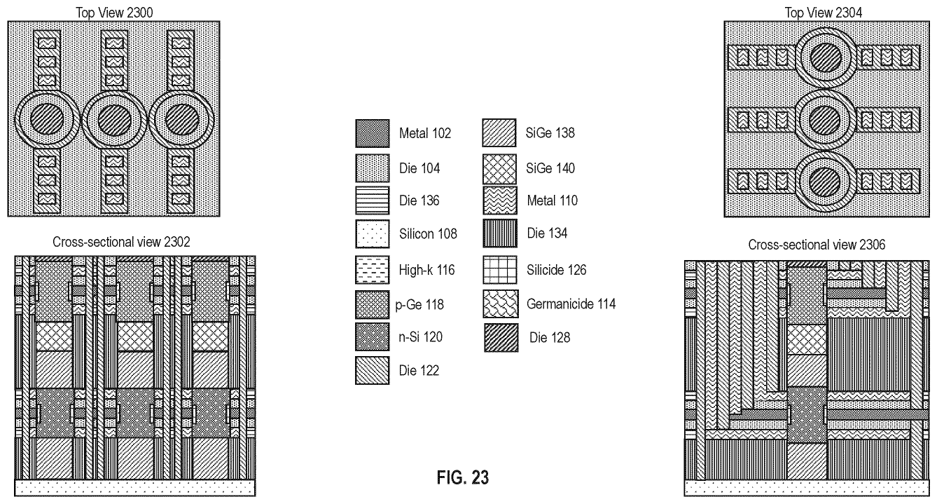

Referring now to FIGS. 23-26, separate SiGe layers or SiGe type materials can be used for enhancing the compatibility of epi-growth of n-Si 120 and p-Ge 118 device. This can also allow for the deposition of separate metals for forming different kinds of silicide 126 and germanicide 114 (silicide regions 255 or germanicide regions 250). As with the techniques and/or structures discussed in connection with FIGS. 1-9, initially deposited dielectric layers can be etched during the process and replaced with metal contact layers (e.g., 102, 110).

Referring now to FIG. 23, cross-sectional views 2302 and 2306 and top views 2300 and 2304 are illustrated in which, fabrication steps similar to those explained in FIG. 16 can be implemented, however in this instance without metal 102 stacks.

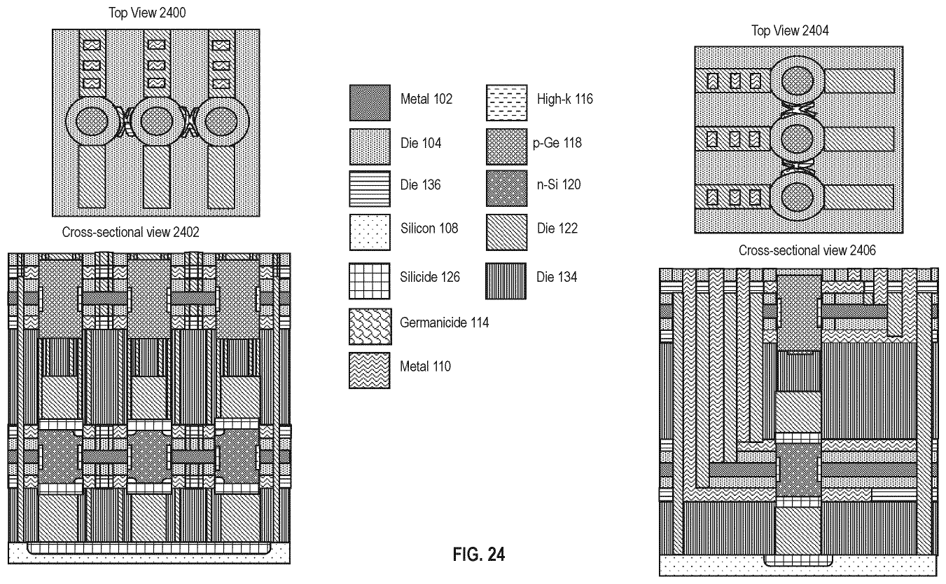

Referring now to FIG. 24, cross-sectional views 2402 and 2406 and top views 2400 and 2404 are illustrated in which, fabrication steps similar to those explained in FIG. 19 can be implemented, however in this instance without metal 102 stacks.

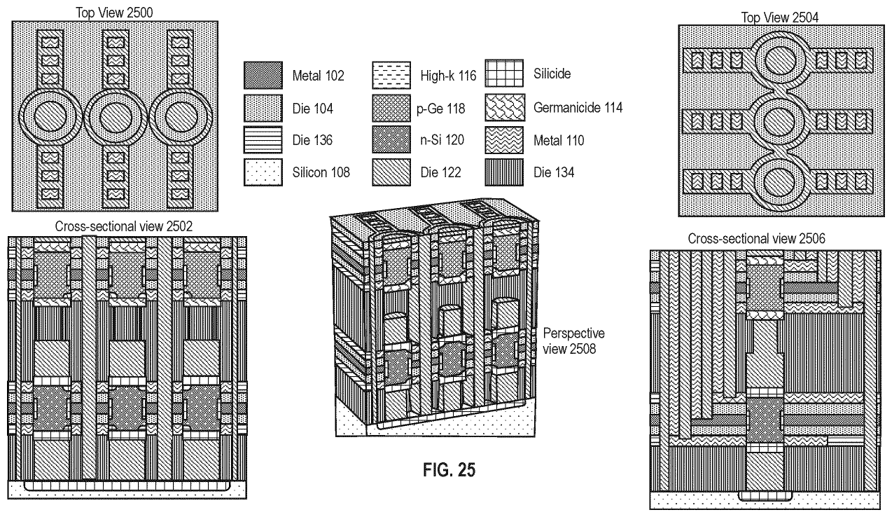

Referring now to FIG. 25, cross-sectional views 2502 and 2506, top views 2500 and 2504 and perspective view 2508 are illustrated in which, similar fabrication steps as those explained in FIG. 21 can be implemented with the current stack without metal 102. The resulting structure may have an air gap between adjacent stacked devices.

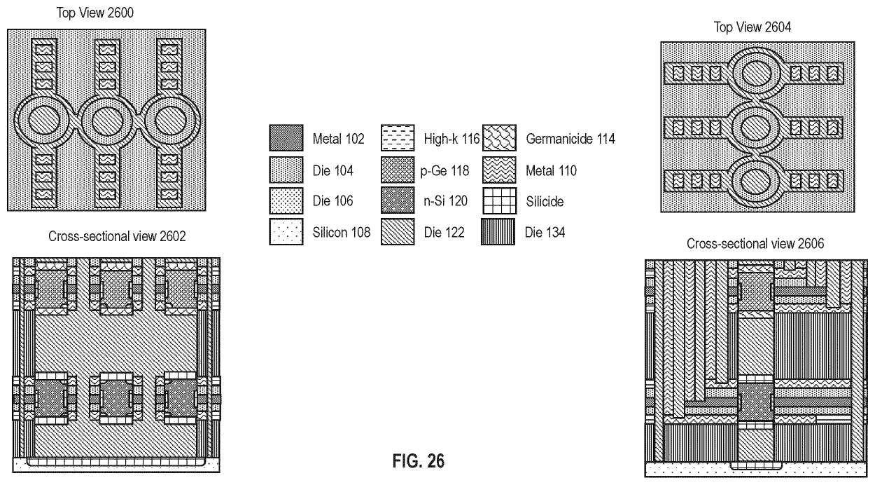

Referring now to FIG. 26, cross-sectional views 2602 and 2606 and top views 2600 and 2604 are illustrated in which, similar fabrication steps as those explained in FIG. 22 can be implemented with the current stack without metal 102. The resulting structure may include no air gap between adjacent stacked devices, but rather include dielectric filling.

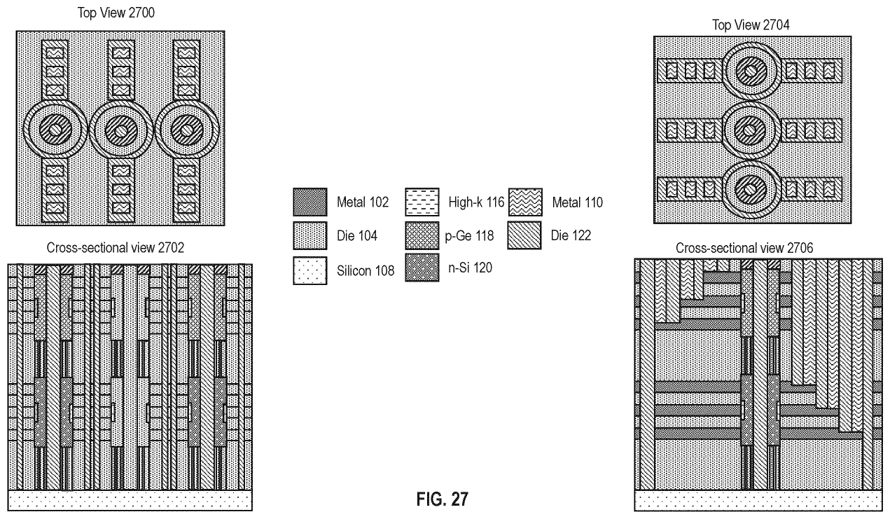

Referring now to FIG. 27, cross-sectional views 2702 and 2706 and top views 2700 and 2704 are illustrated in which two devices stacked without silicide 126 or germanicide 114 formed at the source 215 and drain 225 ends of the device. In FIG. 27, following the trench hole concept demonstrated earlier (e.g., FIG. 6, FIG. 9), the SiGe material layer has been etched and CVD deposition by dielectric 122 and CMP can be implemented. Metal strips steps can be implemented as described in FIG. 22 and FIG. 26.

Moreover, as with the example in FIG. 8, a portion of the device region can be replaced by a dielectric material. As with all the above implementations, an n- and p-type devices are illustrated as examples of any semiconductor devices, but same type or different type devices may be stacked in any suitable arrangement for a given application. Thus, as an example, different 3D semiconductor devices are provided in a 3D stack with Si for NMOS and Ge for PMOS. However, two or more different semiconductor materials may be utilized in the 3D device stack. In various implementations separate metals may be utilized to form the silicide 126 or Germanicide 114 of the silicon and Ge regions respectively allowing for optimum high mobility and conductivity.

Various implementations show air gaps or dielectric cores or fills. These concepts may be utilized in any suitable combination with any suitable device features. One flow shows two separate SiₓGe₁₋ₓ, and Si_{y},Ge_{1-y} selective epi grown layers were used for enhancing the compatibility of epi-growth of adjacent n-Si 120 and p-Ge 118 devices. This robust solution stack enables deposition of separate metals that allows forming optimum Silicide 126 and Germanicide 114 formation.

At a high level, the present solution provides for one or more different 3D semiconductor devices in a 3D stack, using, for example, Si for NMOS and Ge for PMOS, although reversed arrangements as well as arrangements involving other semiconductors are contemplated. Depending on the embodiments, the present solution can utilize two or more different semiconductor devices in the stack of materials used to manufacture the 3D devices. The present solution can allow for separate silicide or germanicide of the Si or Ge regions, respectively and independently, and thereby provide for high mobility and conductivity of the devices. The present solution can include a cavity or a hollow core extending through the central portion of the device regions, as well as beneath and above the device regions, comprising air gap or a dielectric material filling for electrical insulation. The present solution can include two separate epitaxially grown layers of SiₓGe₁₋ₓ and Si_{y}Ge_{1-y} to be used for enhancing the compatibility of epi-growth of adjacent n-Si and p-Ge devices. This can allow for deposition of separate metals for forming silicide and germanicide regions. The present solution can provide high density vertical 3D access to silicide and germanicide regions with integrated 3D isolation and with multiple metal routing option. The present solution can be implemented with a plurality of semiconductor materials compatible with CMOS devices.

The present solution can allow for designing the spacing between neighboring transistor devices to reach the ultimate scaling limit that can exceed the lithographic printing resolution due to the metal gate first core approach. The present solution can include one or more process flows or techniques for fabricating semiconductor circuits, as can be shown with high performance materials that may not utilize epitaxial growth. The present solution can allow for the fabrication of a stack of N transistors in height and can use utilize conductive oxides along with any semiconductive materials. The present solution can allow for a fabrication of a double node transistor.

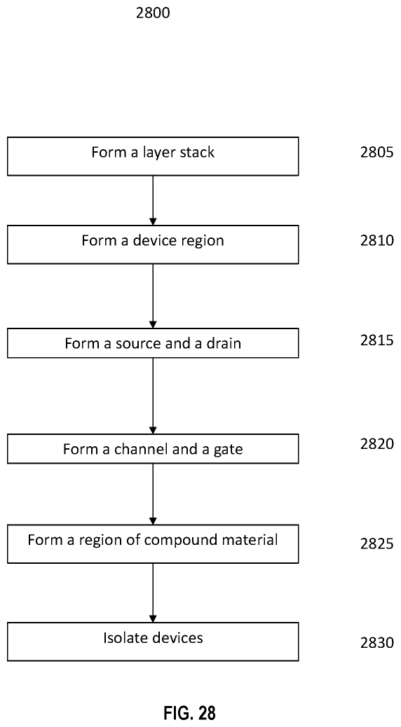

Referring now to FIG. 28, illustrated is a flow diagram of an example method 2800 for fabricating vertical transistor structures 205 using any combination of the fabrication techniques and steps described in FIGS. 1-27. The method 2800 can include steps 2805-2830. At step 2805, a layer stack is formed. At step 2810, a device region is formed. At step 2815, a source and a drain are formed. At step 2820, a channel and gate are formed. At step 2828, a region of compound material is formed. At step 2830, devices are isolated.

At step 2805, method 2800 forms a layer stack. The method can form a stack of layers upon a substrate. The stack of layers can include a source contact layer, a gate contact layer with a first insulation layer between the gate contact layer and the source contact layer and a drain contact layer with a second insulation layer between the gate contact layer and the drain contact layer. Each of the source contact layer, the gate contact layer and the drain contact layer can include a layer of metal material formed or deposited between two layers of dielectric material. The stack of layers can include one or more layers of metal deposited on a substrate along with one or more layers of dielectric in an alternating fashion such that each metal layer is separated from another metal layer by an intervening layer of dielectric. The stack of layers can be formed, for example, in accordance with the layout and/or techniques discussed in connection with FIG. 1 or FIG. 10.

At step 2810, method 2800 forms a device region. The method can form a device region orthogonal to a plane defined by a surface of at least one of the layers in the stack of layers. The device region can include a dielectric surrounded by the source, drain, and channel. The device region can be formed by epitaxially growing semiconductor material inside of a hollow cavity etched vertically downward into the layer stack (e.g., orthogonal to the plane of the substrate). The device region can include epitaxially grown doped silicon. The device region can include epitaxially grown doped germanium. The device can include any combination of epitaxially grown silicon and germanium. The device region can be vertically aligned such that its first source or drain is at the top, its gate is beneath the source or drain and its second (e.g., remaining) source or drain is at the bottom of the device region. Device region can include cylindrical shape, having a circular, elliptical or polygonal cross-section. Device region can include a ring-shaped cross-section as its cross-section can include a hollow core drilled or etched down the center of the device region, leaving the source, drain and channel portions in the ring-shaped portion of the device region. In such an implementation, the device region can be shaped as a hollow cylinder. The cylinder's interior or exterior surface can include a cross-section that is any one of: circular, elliptical, triangular, square, pentagonal, hexagonal, octagonal, decagonal, dodecagonal, or otherwise polygonal with any number of sides. The cross-sectional plane of the device region can be parallel to one or more of the plane of the substrate or the layers of material stack. Device region can be formed, for example, in accordance with steps or techniques discussed in connection with FIG. 2 or FIG. 11.

At step 2815, method 2800 forms a source and a drain. The method can form a source of the device region and a drain of the device region. The source can include a portion of the device region that is at a first end of the vertically oriented device region and the drain can include a portion of the device region at the second end (e.g., opposite to the first end) of the device region. The source and the drain can be composed of the same epitaxially grown semiconductor material from which device region is formed. The source and the drain can be formed in doped silicon or doped germanium. The source and the drain can be formed, for example, in accordance with steps or techniques discussed in connection with FIG. 2 or FIG. 11.

At step 2820, method 2800 forms a channel and a gate. The method can form a channel region that is at least partially surrounded by a gate dielectric interposed between the gate contact layer and the channel region to form a gate of the device region. The channel region can separate the source from the drain. The gate contact layer can be formed to at least partially surround the channel region with a gate dielectric interposed between the gate contact layer and the channel region. The gate contact layer can be formed into a ring around the channel region with a gate dielectric interposed between the gate contact layer and the channel region. The source, the gate and the drain can be vertically aligned and orthogonal to the plane.

At step 2828, method 2800 forms a region of compound material. The region of compound material can include one or more of silicide or germanicide. The method can form a first region comprising one of a silicide or germanicide at a first end of the device region proximal to the source and a second region comprising the one of the silicide or germanicide at a second end of the device region proximal to the drain. The first silicide region at a first end of the device region can be in electrical contact with the source and a second silicide region at a second end of the device region can be in electrical contact with the drain. The first germanicide region at a first end of the device region can be in electrical contact with the source and a second germanicide region at a second end of the device region can be in electrical contact with the drain. The source contact layer can be in electrical contact with the source via a first silicide region of the silicide regions and the drain contact layer is in electrical contact with the drain via a second silicide region of the silicide regions. A germanicide region can interface between a germanium and a metal contact for one of the source or drain. A silicide region can interface between silicon and a metal contact for one of the source or drain. The compound material regions can be formed for example, in accordance with steps or techniques discussed in connection with FIG. 7 or FIG. 13.

At step 2830, method 2800 isolates the devices. The method can form a hollow core extending orthogonally through a central portion of the device region. The hollow core can include one of air or dielectric material. The method can use one or more SiGe materials, SiGe alloys or layers to form a separation between a first device region and a second device region that is formed above the first device region. The space between the two device regions can include air gap or dielectric material to provide electrical insulation. Devices, or device regions, can be isolated or insulated from each other, for example, in accordance with steps or techniques discussed sporadically across FIGS. 2-9 and/or FIGS. 11-14, 15-22 and 23-24.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features described only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A transistor structure comprising:
a stack of layers including:
a first device, comprising:
a first insulation layer between a source contact layer and a gate contact layer and a second insulation layer between a drain contact layer and the gate contact layer; and
a device region orthogonal to a plane defined by a surface of at least one of the layers in the stack of layers, the device region comprising a first semiconductor material, a source and drain separated by a channel region; and
a second device vertically aligned with the first device, comprising:
a third insulation layer between a second source contact layer and a second gate contact layer and a fourth insulation layer between a second drain contact layer and the second gate contact layer; and
a second device region orthogonal to the plane and comprising a second semiconductor material, a second source and a second drain separated by a second channel region.

2. The transistor structure of claim 1 wherein the gate contact layer at least partially surrounds the channel region with a gate dielectric interposed between the gate contact layer and the channel region; and
wherein the first device comprises silicide regions at ends of the device region proximal to the source and the drain and the second device comprises germanicide regions at ends of the second device region proximal to the second source and the second drain.

3. The transistor structure of claim 1 wherein the gate contact layer forms a ring around the channel region with a gate dielectric interposed between the gate contact layer and the channel region.

4. The transistor structure of claim 1 wherein the device region of the first device comprises silicon and the second device region of the second device comprises germanium.

5. The transistor structure of claim 1, comprising:
a first silicide region at a first end of the device region in electrical contact with the source and a second silicide region at a second end of the device region in electrical contact with the drain.

6. The transistor structure of claim 1, comprising a hollow core extending orthogonally through a central portion of the device region, wherein the hollow core comprises one of air or dielectric material.

7. The transistor structure of claim 5, wherein the source contact layer is in electrical contact with the source via the first silicide region and the drain contact layer is in electrical contact with the drain via a second silicide region.

8. The transistor structure of claim 7, wherein the source, the gate and the drain are vertically aligned and orthogonal to the plane and the second source, the second gate and the second drain are vertically aligned and orthogonal to the plane.

9. A gate all around (GAA) transistor structure comprising:
a stack of layers upon a substrate, the stack of layers including:
a first device comprising:
a first insulation layer separating a source contact layer from a gate contact layer and a second insulation layer separating a drain contact layer from the gate contact layer; a device region orthogonal to a plane defined by a surface of at least one of the layers in the stack of layers, the device region comprising a source and drain separated by a channel region that is at least partially surrounded by a gate dielectric interposed between the gate contact layer and the channel region; and
a first region comprising a first silicide formed at a first end of the device region proximal to the source and a second region comprising a second silicide formed at a second end of the device region proximal to the drain; and
a second device comprising:
a third insulation layer separating a second source contact layer from a second gate contact layer and a fourth insulation layer separating a second drain contact layer from the second gate contact layer;
a second device region orthogonal to the plane and comprising a second source and a second drain separated by a second channel region that is at least partially surrounded by a second gate dielectric interposed between the second gate contact layer and the second channel region; and
a third region comprising a first germanicide formed at a first end of the second device region proximal to the second source and a fourth region comprising a second germanicide formed at a second end of the second device region proximal to the second drain.

10. The GAA transistor structure of claim 9, wherein the device region comprises doped silicon and the second device region comprises doped germanium.

11. The GAA transistor structure of claim 9, wherein the first device and the second device are vertically aligned.

12. The GAA transistor structure of claim 9, wherein the source contact layer is in electrical contact with the source via the first region and the drain contact layer is in electrical contact with the drain via the second region.

13. The GAA transistor structure of claim 9, wherein the source, the gate and the drain are vertically aligned and orthogonal to the plane and the second source, the second gate and the second drain are vertically aligned and orthogonal to the plane.

14. The GAA transistor structure of claim 9, comprising a hollow core extending orthogonally through a central portion of the device region, wherein the hollow core comprises at least one of air and a dielectric material.

15. The GAA transistor structure of claim 9, wherein the source contact layer is in electrical contact with the source via a first silicide region of the silicide regions and the drain contact layer is in electrical contact with the drain via a second silicide region of the silicide regions.

16. A method comprising:
forming a stack of layers upon a substrate, the stack of layers including:
a first device, comprising:
a source contact layer;
a gate contact layer with a first insulation layer between the gate contact layer and the source contact layer; and
a drain contact layer with a second insulation layer between the gate contact layer and the drain contact layer;
forming a device region orthogonal to a plane defined by a surface of at least one of the layers in the stack of layers, including:
forming a source of the device region and a drain of the device region;
forming a channel region that is at least partially surrounded by a gate dielectric interposed between the gate contact layer and the channel region to form a gate of the device region, the channel region separating the source from the drain; and
forming a first region comprising a first silicide at a first end of the device region proximal to the source and a second region comprising the second silicide at a second end of the device region proximal to the drain; and
a second device, comprising:
a second source contact layer;
a second gate contact layer with a third insulation layer between the second gate contact layer and the source contact layer; and
a second drain contact layer with a fourth insulation layer between the second gate contact layer and the second drain contact layer;
forming a second device region orthogonal to the plane, including:
forming a second source of the second device region and a second drain of the second device region;
forming a second channel region that is at least partially surrounded by a second gate dielectric interposed between the second gate contact layer and the second channel region to form a second gate of the second device region, the second channel region separating the second source from the second drain; and
forming a third region comprising a first germanicide at a first end of the second device region proximal to the second source and a fourth region comprising a second germanicide at a second end of the second device region proximal to the second drain.

17. The method of claim 16, further comprising forming a hollow core extending orthogonally through a central portion of the device region, wherein the hollow core comprises one of air or dielectric material.

18. The method of claim 16, forming, by the gate contact layer, a ring around the channel region with the gate dielectric interposed between the gate contact layer and the channel region.

19. The method of claim 16, wherein the device region comprises doped silicon and the first region comprises silicide.

20. The method of claim 16, wherein the device region comprises doped germanium and the first region comprises germanicide.
